(19) United States
(12) Patent Application Publication
(10) Pub. No.: US 2016/0064640 A1
(43) Pub. Date: Mar. 3, 2016

(54) POWER SUPPLY DEVICE AND POWER SUPPLY METHOD

(71) Applicant: Samsung Electro-Mechanics Co., Ltd., Suwon-si (KR)

(72) Inventors: In Wha JEONG, Suwon-si (KR); Jong Heum PARK, Suwon-si (KR); Hugh KIM, Suwon-si (KR)

(73) Assignee: SAMSUNG ELECTRO-MECHANICS CO., LTD., Suwon-si (KR)

(21) Appl. No.: 14/658,791

(22) Filed: Mar. 16, 2015

(30) Foreign Application Priority Data
Sep. 1, 2014 (KR) 10-2014-0115674
Oct. 27, 2014 (KR) 10-2014-0146155

(51) Int. Cl. H01L 41/04; H01L 41/107; H02M 5/12

(52) U.S. Cl. CPC H01L 41/044; H02M 5/12; H01L 41/107

(57) ABSTRACT

There are provided a power supply device and a method for power supplying using the same. The power supply device may include a piezoelectric transformer unit including a plurality of piezoelectric layers, and a detecting unit detecting a feedback voltage by using at least one of the plurality of piezoelectric layers.

### CROSS-REFERENCE TO RELATED APPLICATIONS

This application claims priority to, and the benefit of, Korean Patent Application Nos. 10-2014-0115674 filed on Sep. 1, 2014 and 10-2014-0146155 filed on Oct. 27, 2014, with the Korean Intellectual Property Office, the disclosures of which are incorporated herein by reference.

### BACKGROUND

The present disclosure relates to a power supply device and a power supply method.

In the case of small and portable electronic devices, high density and high power efficiency are important issues in designing power supply devices.

To achieve high density and high efficiency, a switching frequency may be increased in power supply devices. This is because the size of a device, such as a transformer, can be reduced when the switching frequency of the device is increased.

However, the high density may cause an increase in the EMI noise at the switching frequency.

To overcome the above problem, a power supply device in which a simplified and thinned piezoelectric transformer is employed has been proposed. Unfortunately, a piezoelectric transformer requires an additional circuit for obtaining a feedback voltage, thereby increasing the overall size of a device. In addition, determination of whether or not a breakage has occurred may be somewhat difficult.

In the related art, there have been approaches to these issues, for example, that disclosed in Korean Patent Laid-Open Publication No. 2001-0029928, and that disclosed in Korean Patent Laid-Open Publication No. 2014-0017450.

### RELATED ART DOCUMENT

(Patent Document 1) Korean Patent Laid-Open Publication No. 2001-0029928
(Patent Document 2) Korean Patent Laid-Open Publication No. 2014-0017450

### SUMMARY

An aspect of the present disclosure may provide a power supply device and a power supply method capable of obtaining a feedback voltage with a simple structure.

According to an aspect of the present disclosure, a power supply device may include a piezoelectric transformer unit including a plurality of piezoelectric layers, and a detecting unit detecting a feedback voltage by using at least one of the plurality of piezoelectric layers.

### BRIEF DESCRIPTION OF DRAWINGS

The above and other aspects, features and advantages of the present disclosure will be more clearly understood from the following detailed description taken in conjunction with the accompanying drawings, in which:

FIG. 1 is a schematic perspective view showing a power supply device according to an exemplary embodiment of the present disclosure;

FIG. 2 is a cross-sectional view taken along line A-A′ of FIG. 1;

FIG. 3 is a schematic perspective view showing a power supply device according to another exemplary embodiment of the present disclosure;

FIG. 4 is a cross-sectional view taken along line B-B′ of FIG. 3;

FIG. 5 is a schematic perspective view showing a power supply device according to another exemplary embodiment of the present disclosure;

FIG. 6 is a cross-sectional view taken along line C-C′ of FIG. 5;

FIG. 7 is a block diagram of a power supply device according to an exemplary embodiment of the present disclosure;

FIG. 8 is a block diagram of a power supply device according to another exemplary embodiment of the present disclosure;

FIG. 9 is a block diagram of a power supply device according to another exemplary embodiment of the present disclosure; and

FIG. 10 is a flowchart illustrating a power supply method according to an exemplary embodiment of the present disclosure.

### DETAILED DESCRIPTION

Exemplary embodiments of the present disclosure will now be described in detail with reference to the accompanying drawings.

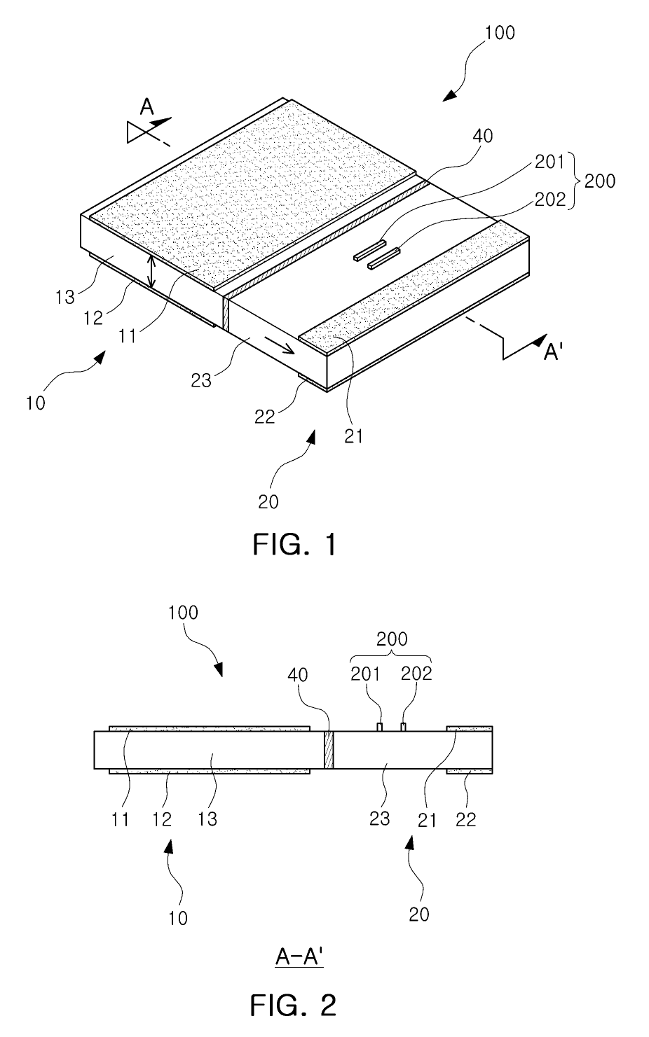

FIG. 1 is a schematic perspective view of a power supply device according to an exemplary embodiment of the present disclosure; and FIG. 2 is a cross-sectional view taken along line A-A′ of FIG. 1.

Referring to FIGS. 1 and 2, the power supply device may include a piezoelectric transformer 100 and a detecting unit 200.

The piezoelectric transformer 100 is a transformer utilizing piezoelectric effect and may include an input section 10 and an output section 20. In some exemplary embodiments, the piezoelectric transformer 100 may further include an insulation layer 40.

The input section 10 may include an input piezoelectric element 13 and input electrodes 11 and 12. The input electrodes 11 and 12 may be formed on two faces of the input piezoelectric element 13 in order to apply an input voltage.

The output section 20 may include an output piezoelectric element 23 and output electrodes 21 and 22. The output electrodes 21 and 22 may be formed on two faces of the output piezoelectric element 23 in order to output an output voltage.

The input piezoelectric element 13 and the output piezoelectric element 23 each may be a stack of a plurality of piezoelectric layers. In the plurality of piezoelectric layers, internal electrodes may be formed alternately, each of the internal electrodes may be connected to respective output electrodes depending on its polarity.

The input piezoelectric element 13 may be polarized in a direction different from a direction in which the output piezoelectric element 23 is polarized. For example, the input piezoelectric element 13 may be polarized in a thickness direction whereas the output piezoelectric element 23 may be polarized in a length direction.

When an input voltage having a resonant frequency is applied to the input piezoelectric element 13, the input piezoelectric element 13 can generate mechanical energy. The output piezoelectric element 23 can output electric energy using the physical energy of the input piezoelectric element 13. In the above example, since the input piezoelectric element 13 is polarized in the thickness direction, it may vibrate in the thickness direction upon applying an input voltage thereto. Such vibration can cause vibration of the adjacent output piezoelectric element 23 in the length direction, so that the output piezoelectric element 23 can use the vibration in the length direction to output an output voltage on the secondary side.

The ratio of an output voltage on the secondary side to an input voltage on the primary side may be determined depending on the electrode geometry and the like between the input piezoelectric element 13 and the output piezoelectric element 23. Therefore, the output from the output piezoelectric element 23 side, i.e., output voltage on the secondary side may be a transformed voltage (hereinafter, referred to as “transformed voltage”).

In an exemplary embodiment, the piezoelectric transformer 100 may further include an insulation layer 40 between the input section 10 and the output section 20. The insulation layer 40 maybe made of various insulative material. For example, the insulation layer 40 may be made of a highly insulative material such as ceramic.

The insulation layer 40 may be a resin sheet or film.

In an exemplary embodiment, as the insulation layer 40, a thin film which is insulative as well as flexible may be used. A thin-film insulation layer 40 is advantageous over a ceramic insulation layer 40, because cracks or breakage may occur in the ceramic insulation layer 40 due to the degree of fatigue increased by vibrations. Alternatively, due to rigidity of ceramic material, the vibrations of the input section 10 may not be transmitted effectively to the output section 20.

In an exemplary embodiment, at least one void may be formed in the insulation layer 40. The void is filled with air or is an empty space (vacuum state), so that the input section 10 can be electrically insulated from the output section 20 by means of the void.

By forming the void, the actual volume of the insulation layer 40 can be significantly reduced, so that the insulation layer 40 has the minimal area and the attenuation of the vibrations from the input section 10 is reduced. Accordingly, the vibration can be transmitted efficiently to the output section 20.

The detecting unit 200 may detect a feedback voltage using at least a portion of the thickness of the output piezoelectric element 23. In other words, the detecting unit 200 can detect the feedback voltage using at least one of the plurality of piezoelectric layers of the output piezoelectric element 23.

In an exemplary embodiment, the detecting unit 200 may include a first detection electrode 201 attached to a first point of the output piezoelectric element 23 and a second detection electrode 202 attached to a second point of the output piezoelectric element 23. In this regard, the first point and the second point may be spaced apart by a gap equal to the thickness of at least one of the plurality of piezoelectric layers of the output piezoelectric element 23.

Namely, the transformed voltage may be output by the overall piezoelectric layers of the output piezoelectric element 23, whereas the feedback voltage may be detected using at least one of the piezoelectric layers of the output piezoelectric element 23.

According to existing techniques to obtain a feedback voltage, before detecting a feedback voltage, an additional circuit for reducing the transformed voltage output from an output piezoelectric element is required. In contrast, according to exemplary embodiments of the present disclosure, the feedback voltage can be detected by using at least one of the overall piezoelectric layers of the output piezoelectric element 23, without employing such an additional circuit. Thus, the configuration of the entire circuit becomes simpler while the feedback voltage can be obtained accurately.

In an exemplary embodiment, the detecting unit 200 can detect the feedback voltage by reflecting the ratio of the number of used piezoelectric layers to the number of the overall piezoelectric layers of the output piezoelectric element 23. Accordingly, the magnitude of the feedback voltage can be adjusted by adjusting the gap between the first detection electrode 201 and the second detection electrode 202 of the detecting unit 200.

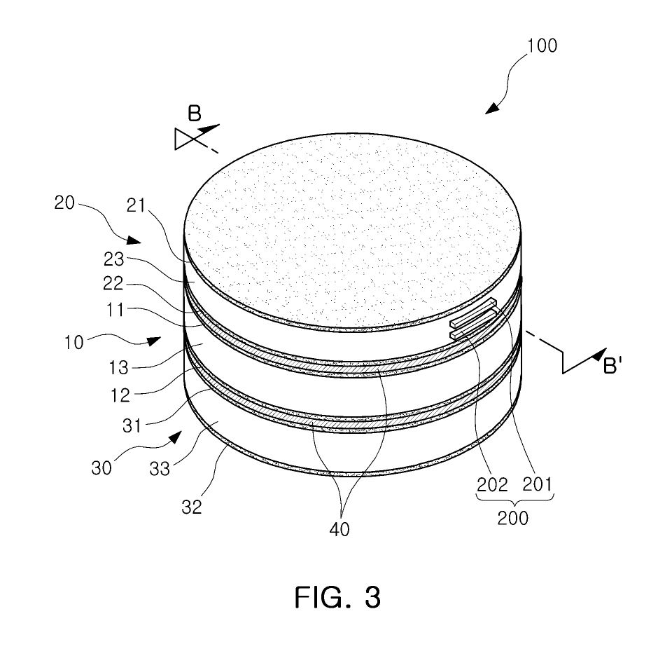

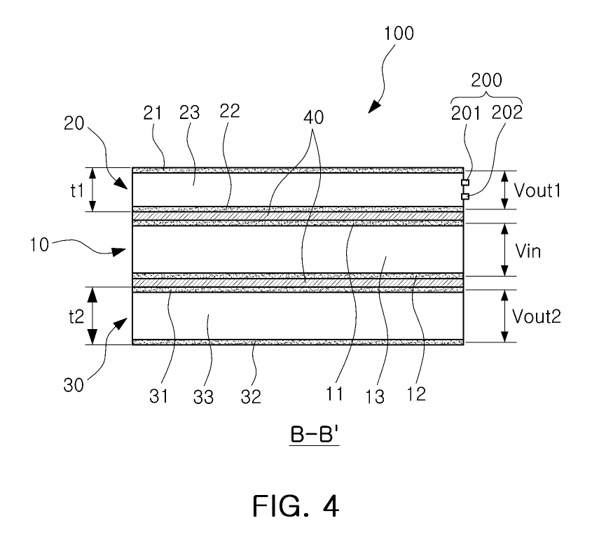

FIG. 3 is a schematic perspective view of a power supply device according to another exemplary embodiment of the present disclosure; and FIG. 4 is a cross-sectional view taken along line B-B′ of FIG. 3.

Referring to FIGS. 3 and 4, the power supply device may include a piezoelectric transformer 100 and a detecting unit 200.

The piezoelectric transformer 100 according to this exemplary embodiment is of a stacked piezoelectric transformer and may include an input section 10 and the output sections 20 and 30, similarly to the above-described exemplary embodiment. In some exemplary embodiments, the piezoelectric transformer 100 may further include an insulation layer 40.

In this exemplary embodiment, the output sections 20 and 30 may be formed on the upper and lower faces of the input section 10, respectively. Each of the output sections 20 and 30 may include output piezoelectric elements 23 and 33, respectively, and electrode layers 21 and 22; 31 and 32, formed on the upper and lower faces of the respective output piezoelectric elements 23 and 33 for outputting output voltages, respectively.

Although the input section 10 and the output sections 20 and 30 have a disc shape in this exemplary embodiment, it is merely illustrative but is not limiting. Namely, the input section 10 and the output sections 20 and 30 may have various shapes, such as a poly-prism or an elliptic cylinder, as necessary.

Further, the insulation layer 40 may be formed between the input section 10 and the output sections 20 and 30. The insulation layer 40 may be a flexible thin-film in this exemplary embodiment, although it may be made of ceramic material which is highly insulative as in the above-described exemplary embodiment. Additionally, like the above described exemplary embodiment, at least one void may be formed in the insulation layer 40.

As shown in FIG. 4, the thickness t1 of the first output section 20 may differ from the thickness t2 of the second output section 30. Further, the number of the piezoelectric layers of one of the piezoelectric elements may differ from that of the other. Accordingly, for a single input voltage Vin, the first output section 20 and the second output section 30 may output different voltages Vout1 and Vout2, respectively.

Further, the first output section 20 and the second output section 30 may be polarized either in the same direction or in the opposite direction.

Additionally, although the first output section 20 and the second output section 30 have a disc shape having the same diameter in this exemplary embodiment, they may have different sizes, thicknesses, shapes or the like, as the necessity requires.

The detecting unit 200 can detect the feedback voltage using at least one of the plurality of piezoelectric layers of the output piezoelectric element 23.

In an exemplary embodiment, the detecting unit 200 may detect the feedback voltage by using the first detection electrode 201 and the second detection electrode 202. The first detection electrode 201 and the second detection electrode 202 may be spaced apart from each other by a gap equal to the thickness of at least one of the plurality of piezoelectric layers of the output piezoelectric element 23.

Although only the first output section 20 has the detecting unit 200 by way of example, the second output section 30 may also have the detecting unit 200 in some exemplary embodiments.

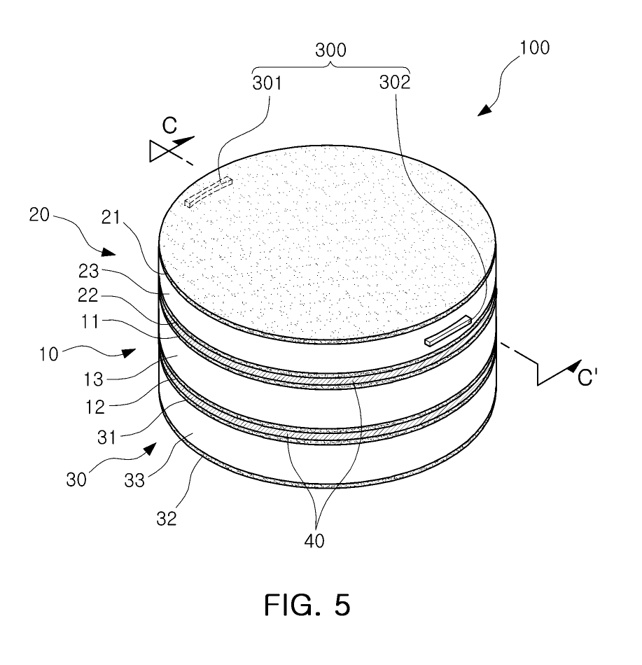

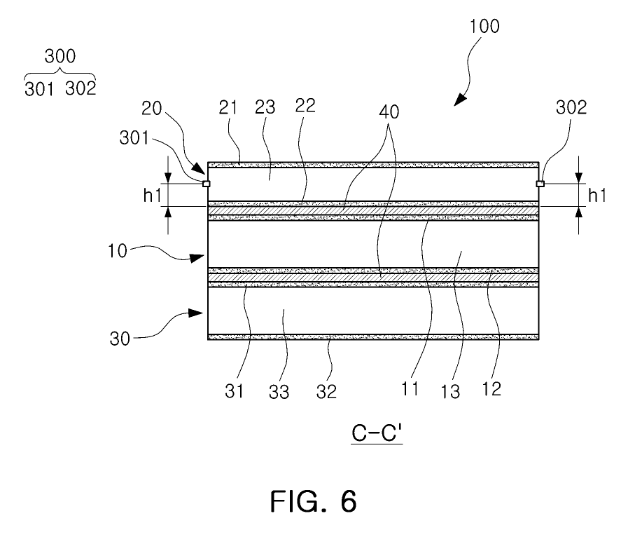

FIG. 5 is a schematic perspective view of a power supply device according to an exemplary embodiment of the present disclosure; and FIG. 6 is a cross-sectional view taken along line C-C′ of FIG. 5.

Referring to FIGS. 5 and 6, the power supply device may include a piezoelectric transformer 100 and a breakage sensing units 301 and 302. Although the breakage sensing units 301 and 302 are disposed on the first output piezoelectric element 23 in FIGS. 5 and 6, the breakage sensing units 301 and 302 may also be disposed other piezoelectric elements, e.g., the input piezoelectric element 13 or the second piezoelectric element 33, as long as they can detect breakage of the piezoelectric elements.

The configuration of the piezoelectric transformer 100 is identical to that described above, and thus the redundant description will be omitted.

The breakage sensing units 301 and 302 can detect breakage of the piezoelectric elements of the piezoelectric transformer 100. Namely, the breakage sensing units 301 and 302 are connected to at least one of the piezoelectric elements 13, 23 and 33 included in the input section 10 or the output sections 20 and 30 so that they can detect the breakage of the piezoelectric element.

In an exemplary embodiment, the breakage sensing units 301 and 302 may include a first electrode 301 attached to a first point of the piezoelectric element and a second electrode 302 attached to a second point of the piezoelectric element. In this regard, the first point and the second point may be disposed on the same piezoelectric layer of the piezoelectric element. In other words, the first electrode 301 and the second electrode 302 may be electrically attached to one of the plurality of piezoelectric layers of the piezoelectric element.

The first electrode 301 and the second electrode 302 at the same height h1, i.e., attached to the same piezoelectric layer have voltages within an error tolerance range. Normally, the first electrode 301 and the second electrode 302 may have the voltages of the same level. However, there may be a preset error tolerance range, and thus voltages detected by the first electrode 301 and the second electrode 302 lie within the error tolerance range.

Therefore, the voltages detected by the first electrode 301 and the second electrode 302 are supposed to be within the error tolerance unless the piezoelectric element is broken.

If the piezoelectric element has been broken, however, the voltage difference exceeds the error tolerance at the points to which the first electrode 301 and the second electrode 302 are attached due to the breakage, respectively. Accordingly, if the piezoelectric element has been broken, the voltage between the first electrode 301 and the second electrode 302 exceeds the preset error tolerance, so that the breakage sensing units 301 and 302 may output a breakage sensing signal.

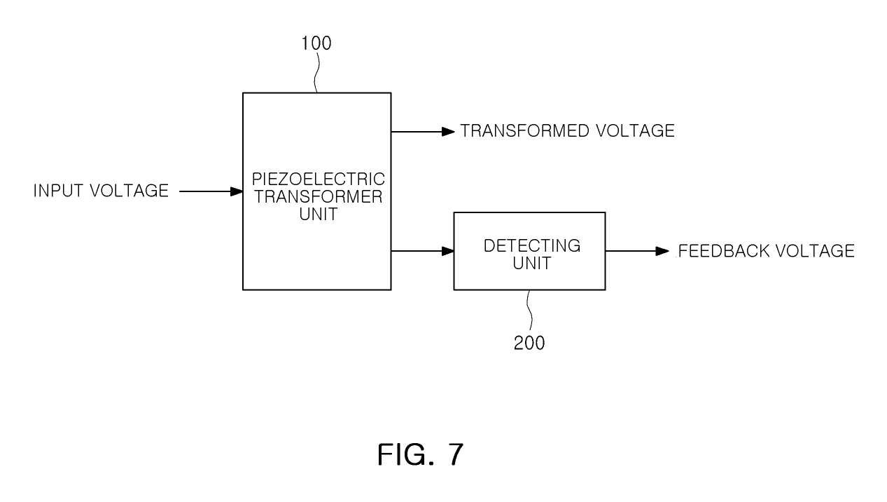

FIG. 7 is a block diagram of a power supply device according to an exemplary embodiment of the present disclosure.

The power supply device shown in FIG. 7 includes a detecting unit 200, and the foregoing descriptions with respect to FIGS. 1 through 4 can be applied to this exemplary embodiment. Accordingly, specific operations of individual elements and examples thereof are identical to those described above with respect to FIGS. 1 through 6; and, therefore, the redundant descriptions will be omitted.

Referring to FIG. 7, the power supply device includes a piezoelectric transformer unit 100 and a detecting unit 200 in this exemplary embodiment.

The piezoelectric transformer unit 100 may include an input section receiving an input voltage, and an output section outputting a transformed signal (e.g., a transformed voltage) using kinetic energy of the input section. Each of the input section and the output section may include a piezoelectric element.

The detecting unit 200 can detect a feedback voltage using at least one of the plurality of piezoelectric layers of the output piezoelectric element of the output section.

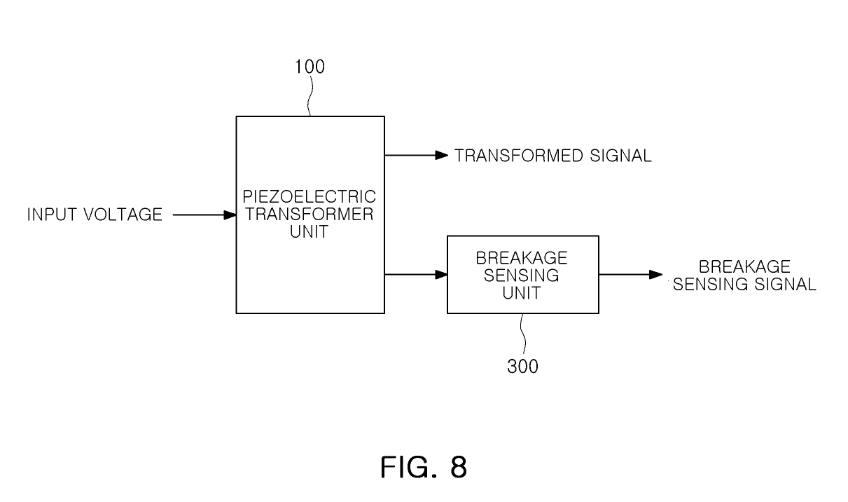

FIG. 8 is a block diagram of a power supply device according to another exemplary embodiment of the present disclosure. The power supply device shown in FIG. 8 includes a breakage sensing unit 300. In some exemplary embodiments, the power supply device may further include a detecting unit.

The piezoelectric transformer unit 100 may include an input section receiving an input voltage, and an output section outputting a transformed signal (e.g., a transformed voltage) using kinetic energy of the input section. Each of the input section and the output section may include a piezoelectric element.

The breakage sensing unit 300 may sense breakage of the piezoelectric element. For example, the breakage sensing unit 300 may include a first electrode and a second electrode electrically attached to one of a plurality of piezoelectric layers included in the piezoelectric element, and may determine that the piezoelectric element has been broken if the voltages detected by the first electrode and the second electrode exceed the error tolerance.

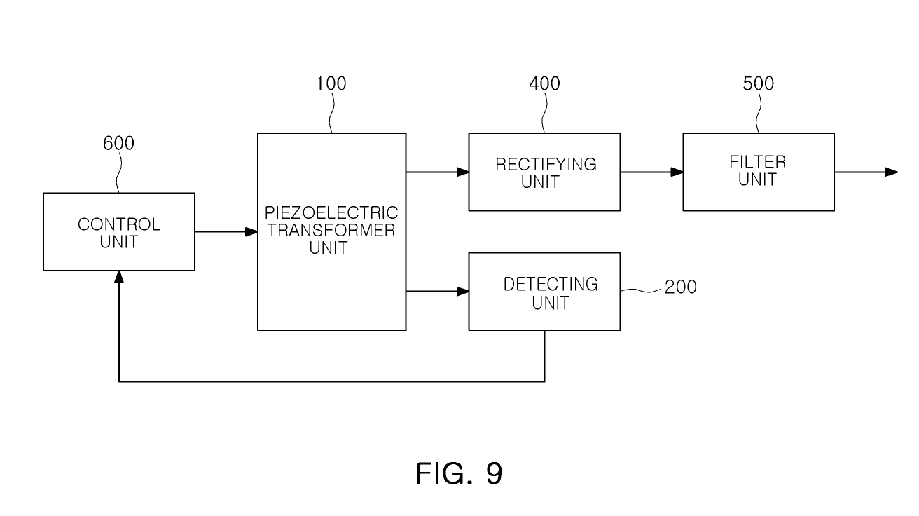

FIG. 9 is a block diagram of a power supply device according to another exemplary embodiment of the present disclosure. In the exemplary embodiment of FIG. 9, a power supply device may include a piezoelectric transformer unit 100, a detecting unit 200 and a control unit 600. In some exemplary embodiments, the power supply device may further include a rectifying unit 400 and/or a filter unit 500.

The piezoelectric transformer unit 100 may output a transformed voltage from an input voltage using a piezoelectric element.

The detecting unit 200 can detect a feedback voltage using at least a portion of the thickness of the piezoelectric element, i.e., at least one of the plurality of piezoelectric layers of the piezoelectric element.

The control unit 600 may perform feedback control using a feedback voltage from the detecting unit 200. The present disclosure does not specifically limit the feedback control by the control unit 600 and thus the description thereof will not be made.

The rectifying unit 400 can rectify the transformed voltage, and the filter unit 500 can perform filtering on the rectified, transformed voltage.

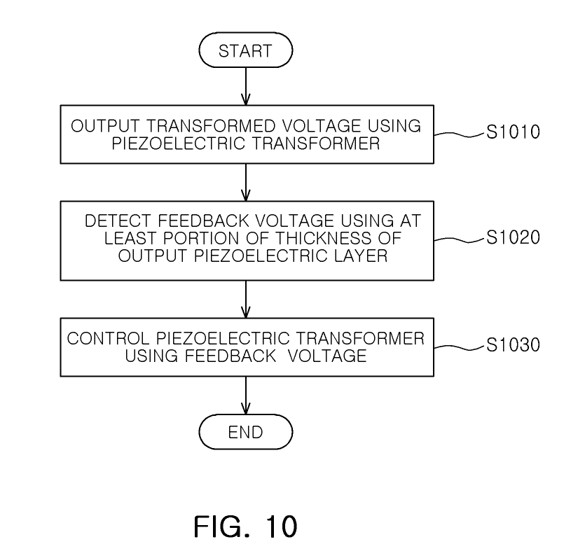

FIG. 10 is a flowchart illustrating a power supply method according to an exemplary embodiment of the present disclosure. The power supply method to be described below may be performed by the power supply device described above with reference to FIGS. 1 through 9; and, therefore, the redundant descriptions will be omitted.

Referring to FIG. 10, the power supply device may apply an input voltage to a piezoelectric transformer to output a transformed voltage (S1010).

The power supply device can detect a feedback voltage using at least one of a plurality of piezoelectric layers of an output piezoelectric element of a piezoelectric transformer (S1020).

The power supply device may control the piezoelectric transformer using a feedback voltage (S1030).

In an exemplary embodiment, the power supply device may determine whether the output piezoelectric element has been broken using a pair of electrodes attached to one of the plurality of piezoelectric layers of the output piezoelectric element.

The power supply device may determine that the output piezoelectric element has been broken if the output voltage between the pair of electrodes is out of a preset error tolerance range.

As set forth above, according to an exemplary embodiment of the present disclosure, a feedback voltage can be easily obtained with a simple structure.

According to another exemplary embodiment of the present disclosure, breakage of a piezoelectric transformer can be easily checked with a simple structure.

While exemplary embodiments have been shown and described above, it will be apparent to those skilled in the art that modifications and variations could be made without departing from the scope of the present invention as defined by the appended claims.

What is claimed is:

1. A power supply device comprising:
a piezoelectric transformer unit including an input piezoelectric element receiving an input voltage, and an output piezoelectric element outputting a transformed voltage; and
a detecting unit detecting a feedback voltage using at least one of a plurality of piezoelectric layers of the output piezoelectric element.

2. The power supply device of claim 1, wherein the detecting unit includes:
a first detection electrode attached to a first point of the output piezoelectric element; and
a second detection electrode attached to a second point of the output piezoelectric element,
wherein the first point and the second point are spaced apart from each other by a gap equal to a thickness of the at least one of the plurality of piezoelectric layers of the output piezoelectric element.

3. The power supply device of claim 1, wherein the detecting unit detects the feedback voltage by reflecting a ratio of the number of the at least one of the plurality of piezoelectric layers used in detecting the feedback voltage to the overall number of the plurality of piezoelectric layers of the output piezoelectric element.

4. The power supply device of claim 1, wherein the output piezoelectric element provides the transformed voltage using mechanical energy of the input piezoelectric element caused by the input voltage.

5. The power supply device of claim 1, further comprising a breakage sensing unit connected to the output piezoelectric element to sense breakages in the output piezoelectric element.

6. The power supply device of claim 5, wherein the breakage sensing unit includes:
a first electrode attached to a first point of the output piezoelectric element; and
a second electrode attached to a second point of the output piezoelectric element,
wherein the first electrode and the second electrode are electrically connected to any one of the plurality of piezoelectric layers of the output piezoelectric element.

7. The power supply device of claim 6, wherein the breakage sensing unit outputs a breakage sensing signal if an output voltage between the first electrode and the second electrode is out of a preset error tolerance range.

8. The power supply device of claim 1, wherein the piezoelectric transformer unit further includes an insulation layer between the input piezoelectric element and the output piezoelectric element.

9. The power supply device of claim 8, wherein the insulation layer includes at least one void therein.

10. The power supply device of claim 8, wherein the insulation layer is a thin film having insulating and flexible properties.

11. A power supply device comprising:
a piezoelectric transformer unit including an input section receiving an input voltage, and an output section providing a transformed voltage; and
a breakage sensing unit connected to a piezoelectric element included in the input section or in the output section to sense breakage of the piezoelectric element.

12. The power supply device of claim 11, wherein the breakage sensing unit includes:
a first electrode attached to a first point of the piezoelectric element; and
a second electrode attached to a second point of the piezoelectric element,
wherein the first electrode and the second electrode are electrically connected to any one of a plurality of piezoelectric layers of the piezoelectric element.

13. The power supply device of claim 12, wherein the breakage sensing unit outputs a breakage sensing signal if an output voltage between the first electrode and the second electrode is out of a preset error tolerance range.

14. A power supply device comprising:
a piezoelectric transformer unit including an input piezoelectric element receiving an input voltage, and an output piezoelectric element outputting a transformed voltage;
a detecting unit detecting a feedback voltage using at least one of a plurality of piezoelectric layers of the output piezoelectric element; and
a control unit controlling the piezoelectric transformer unit using the feedback voltage.

15. A power supply method performed by a power supply device employing a piezoelectric transformer, the method comprising:
applying an input voltage to the piezoelectric transformer to output a transformed voltage;
detecting a feedback voltage using at least one of a plurality of piezoelectric layers of an output piezoelectric element of the piezoelectric transformer; and
controlling the piezoelectric transformer using the feedback voltage.

16. The method of claim 15, further comprising determining breakage of the output piezoelectric element by using a pair of electrodes connected to the same piezoelectric layer of the output piezoelectric element.

17. The method of claim 16, wherein the determining of the breakage of the output piezoelectric element includes determining that the output piezoelectric element has been broken if an output voltage between the pair of electrodes is out of a preset error tolerance range.
